(19) United States
(12) Patent Application Publication
(10) Pub. No.: US 2010/0283138 A1
(43) Pub. Date: Nov. 11, 2010

(54) Nickel-Based Bonding of Semiconductor Wafers

(75) Inventors: Li Chen, Arlington, MA (US); Kuang L. Yang, Newton, MA (US)

Correspondence Address: Sunstein Kann Murphy & Timbers LLP, 125 SUMMER STREET, BOSTON, MA, 02110-1618, US

(73) Assignee: ANALOG DEVICES, INC., Norwood, MA (US)

(21) Appl. No.: 12/436,569

(22) Filed: May 6, 2009

(51) Int. Cl. H01L 23/02; H01L 21/50

(52) U.S. Cl. 257/678; 438/107; 257/E23.18; 257/E21.499

(57) ABSTRACT

A nickel-based material is used on one or both wafers to be bonded, and the two wafers are bonded at low temperature and pressure through interdiffusion of the nickel-based material with either another nickel-based material or aluminum. In various embodiments, nickel-based walls are formed on one wafer, and corresponding walls are formed on the other wafer from a nickel-based material or aluminum. The walls of the two wafers are placed in contact with one another under sufficient pressure and temperature to cause bonding of the walls through interdiffusion.

### CROSS-REFERENCE TO RELATED APPLICATIONS

The present application may be related to one or more of the following commonly-owned patent applications, each of which is hereby incorporated herein by reference in its entirety:

U.S. patent application Ser. No. 11/828,075 entitled WAFER BONDING USING NANOPARTICLE MATERIAL filed Jul. 25, 2007, corresponding to U.S. Publication No. US2009/0029152 (Attorney Docket No. 2550/B41);

U.S. patent application Ser. No. 12/013,310 entitled ALUMINUM BASED BONDING OF SEMICONDUCTOR WAFERS filed Jan. 11, 2008, corresponding to U.S. Publication No. US2008/0237823 (Attorney Docket No. 2550/B82);

U.S. patent application Ser. No. 12/013,208 entitled MEMS SENSOR WITH CAP ELECTRODE filed on Jan. 11, 2008, corresponding to U.S. Publication No. US2008/0168838 (Attorney Docket No. 2550/B86);

U.S. patent application Ser. No. 12/398,774 entitled LOW TEMPERATURE METAL TO SILICON DIFFUSION AND SILICIDE WAFER BONDING filed on Mar. 5, 2009 (Attorney Docket No. 2550/C17); and

U.S. patent application Ser. No. 10/002,953 entitled MEMS CAPPING METHOD AND APPARATUS filed on Oct. 23, 2001, corresponding to U.S. Pat. No. 6,893,574 (Attorney Docket No. 2550/117).

### TECHNICAL FIELD

The present invention relates to bonding of semiconductor wafers.

### BACKGROUND ART

The demand for semiconductor devices, in particular, MEMS devices, is increasing dramatically. Product makers using these semiconductor devices are in turn demanding smaller product size and lower prices. Wafer scale packaging is an important step to providing cost efficient mass production of semiconductor devices. Several wafer scale packaging processes have been reported. For example, U.S. Pat. No. 6,893,574 (Felton et al.), which is commonly owned with the subject patent application, discloses a MEMS capping method and apparatus using cut capture cavities. In the field of MEMS accelerometers, the typical wafer packaging processes include glass frit and anodic bonding.

Glass frit bonding of inertial MEMS devices is hermetic, cost-effective, requires reasonably low process temperatures and readily accommodates wafer topography. Unfortunately, there are a number of limitations suffered by users of glass frit bonding. Screen printing of glass frit does not meet integrated circuit contamination standards, so integration of capping with the fabrication process is not a prudent option. Glass is a dielectric so EMI shielding and control of stray charges require a separate electrical connection to the caps. Package thickness may increase if this connection is a bond wire to the top surface.

Glass frit seals are typically 150 to 400 microns in width on each side of the microstructure. This adds to the overall size of the semiconductor devices. Moreover, glass and silicon have different thermal expansion coefficients so a stress field is set up near the microstructure as the wafers cool from the bonding temperature.

Anodic bonding applies several hundred volts across a glass-silicon bond pair at about 350-420° C. The electric field causes mobile ions in the glass to move away from the interface and towards the cathode (outer surface of the glass wafer). The bound negative charges that remain in the glass near the interface produce a field that pulls the surfaces together and anodically oxidizes the silicon surface. Anodic bonding is fast and applies minimal pressure.

However, anodic bonding has its limitations as well. Flat wafer topography is required because hermetic bonding requires closely mated surfaces. Imposing a high voltage during high temperature bonding limits integration of MEMS and electronics on wafers. Some provision is required to shield the microstructures from electrostatic forces that can cause microstructure stiction during the bonding process. Glass-silicon bond pairs may require wider saw streets than silicon wafers.

An alternative possibility for wafer bonding that has been considered is the use of metals. Two approaches to using metal include solder processes and thermocompression bonding. Solder based processes readily accommodate wafer topography. High temperature solders are preferable because many end-use applications of the capped devices require that they survive plastic package transfer molding stresses at 175° C. Environmental and regulatory considerations make the use of non-lead solders highly desirable. Minimizing solder creep during high temperature aging is also important (solder creep and stress relaxation will affect device parametrics). Gold-tin is a candidate, but gold cannot be used in an integrated circuit fabrication because it is a deep trap contaminant.

Thermocompression bonding requires bond pressures and wafer topography that create atomic-scale contact between the mating metal surfaces. Gold is commonly described as a candidate for thermocompression bonding. Gold is attractive because it is relatively soft and can thus achieve atomic scale contact with reasonable bonder force. Furthermore, it advantageously does not form a native oxide. Gold also forms low temperature eutectics. On the other hand, as noted above, gold generally cannot be used in integrated circuit fabrication.

Thermocompression bonding can also be used in forming electrical connections between wafers. Copper has been used for this application, despite the fact that it is also a deep trap contaminant. Copper is a conductive material which oxidizes. While the oxide interferes with thermocompression bonding, the oxidation of the copper takes place slowly. Thus, processes have been developed that form copper electrical connections between wafers with thermocompression bonding.

U.S. Pat. No. 6,853,067 discloses thermocompression bonding to form a sealed cavity for a MEMS device, in which the bonding features are formed of a relatively soft metal, such as gold, aluminum, copper, tin, or lead, or some alloy thereof (e.g. gold-tin), that is known to thermocompressively bond.

U.S. Publication No. US2008/0237823, which is commonly-owned with the subject patent application, discloses bonding of semiconductor wafers using aluminum-based materials (i.e., aluminum and/or aluminum alloy).

With thermocompression bonding, the force needed to bond the wafers is generally proportional to the surface area being bonded, which itself is generally proportional to the number of devices to be capped. Thus, as wafer fabricators migrate to larger wafers (e.g., 8 inch wafers instead of 6 inch wafers) and/or continue to increase the density of devices on the wafers, both of which tend to increase the surface area to be bonded, more force is generally needed to effectuate wafer bonding.

US2004/232500 discloses hermetically-sealed sensors using a closed ring of aluminum or other low-melting metal (e.g., gold, zinc, etc.) bonded at a temperature of more than 500 degrees Celsius under a low pressure to form a bond through interdiffusion.

U.S. Publication No. US2009/0029152, which is commonly-owned with the subject patent application, discloses wafer bonding using metal nanoparticle materials that may include silver, gold, nickel, tungsten, aluminum, copper and/or platinum.

U.S. Pat. No. 7,442,570, U.S. Pat. No. 7,104,129, and US2008/0283990 disclose aluminum-germanium bonding in wafer packaging environments.

U.S. Pat. No. 3,949,118, U.S. Pat. No. 6,306,516, and U.S. Pat. No. 6,319,617 disclose solders containing rare earth metals.

U.S. Pat. No. 7,329,056 discusses device packaging.

The patents and published patent applications mentioned above, each of which is hereby incorporated herein by reference in its entirety, are exemplary and are not intended to represent an exhaustive list of prior art.

### SUMMARY OF THE INVENTION

In embodiments of the present invention, a nickel-based material is used on one or both wafers to be bonded, and the two wafers are bonded at low temperature and pressure through interdiffusion of the nickel-based material with either another nickel-based material or aluminum. Specifically, in various embodiments, nickel-based walls are formed on one wafer, and corresponding walls are formed on the other wafer from a nickel-based material or aluminum. The walls of the two wafers are placed in contact with one another with a sufficient bonding force and temperature to cause bonding of the walls through interdiffusion. Generally speaking, the force applied to the wafers effectively only needs to be sufficient (i.e., above a predetermined threshold) to maintain contact of the bonding surfaces during the bonding process, and above this threshold, the force is generally independent of the surface area to be bonded such that increases in wafer size and/or device density do not require substantial increases in bonding force (or perhaps any increase at all).

In accordance with one aspect of the invention there is provided bonded wafers having a first wafer including an array of semiconductor dies, each semiconductor die including a microelectronic device; a second wafer; and a configuration of walls forming a bond between the first wafer and the second wafer, wherein each wall comprises an interdiffusion of a first nickel-based material on one wafer with either a second nickel-based material or aluminum on the other wafer.

In accordance with another aspect of the invention there is provided a MEMS device having a device die including a microelectronic device; a cap die; and a wall bonded between the device die and the cap die and at least partially surrounding an area occupied by the microelectronic device, the wall comprising an interdiffusion of a first nickel-based material on one die with either a second nickel-based material or aluminum on the other die.

In accordance with yet another aspect of the invention there is provided a method of making semiconductor devices including depositing a nickel-based material to form a nickel-based layer on a first semiconductor wafer; patterning the nickel-based layer to form a first configuration of nickel-based walls on the first semiconductor wafer; depositing either a nickel-based material or aluminum to form a material layer on a second semiconductor wafer; patterning the material layer to form a configuration of material walls on the second semiconductor wafer; placing the second wafer on the first wafer so that the configuration of nickel-based walls on the first wafer aligns with the configuration of walls on the second wafer; heating the first and second wafers; compressing the first and second wafers against each other to form a bond between the walls on the first wafer and their respective walls on the second wafer through interdiffusion; and singulating the first and second wafers into individual semiconductor devices, each having bonded wall.

In various alternative embodiments, patterning may including etching, heating may be performed at a temperature up to less than 500° C. (e.g., around 450° C. to 470° C.), and compressing may be performed at a force between around 9 and 18 KN (Kilo-Newtons). An anti-stiction layer may be included on the device wafer/die. An annealing process may be performed after bonding in order to strengthen the bond.

In any of the above-mentioned embodiments, bonding may be through interdiffusion of nickel and aluminum or may be through interdiffusion of two nickel-based materials, which may be the same or different nickel-based materials. One or both of the wafers/dies may include a microelectronic device (e.g., a MEMS device), and one or both of the wafers/dies may include electronic circuitry. The walls may partially or fully surround a microelectronic device and may provide a hermetically sealed cavity around the device, which may be filled with a fluid or evacuated. The walls may provide an electrically conductive path between the two wafers/dies. The walls may hold the wafers/dies at least 2 microns apart, and may have a wall width between 3 and 90 microns and more specifically between 5 and 30 microns. Wafers used for capping may be substantially flat or may include cavities.

### BRIEF DESCRIPTION OF THE DRAWINGS

The foregoing features of the invention will be more readily understood by reference to the following detailed description, taken with reference to the accompanying drawings, in which:

FIG. 1 is a flow chart of an embodiment of a method of the present invention.

FIG. 2 is a plan view of a wafer with an array of deposited nickel-based rings in accordance with the method of FIG. 1.

FIG. 3 is a side view of bonded wafers made according to the method of FIG. 1.

FIG. 4 is a side cross-sectional view of a MEMS device of an embodiment of the present invention.

FIG. 5 is a plan view of the cap in the MEMS device of FIG. 4.

### DETAILED DESCRIPTION OF SPECIFIC EMBODIMENTS

Definitions. As used in this description and the accompanying claims, the following terms shall have the meanings indicated, unless the context otherwise requires.

The term “nickel-based” means made from nickel or an alloy of predominantly nickel with aluminum.

The term “wall” means either a structure on a wafer that is used for bonding to a corresponding wall structure on another wafer or the resultant structure formed by such bonding. A wall may, but is not required to, form an enclosed area (e.g., a ring formation).

The term “MEMS device” means any of a variety of microelectromechanical systems such as, for example, including one or more of inertial sensors such as accelerometers (e.g., capacitive, piezoelectric, convective, etc.) or gyroscopes (e.g., vibratory, tuning fork, etc.), microphones, pressure sensors, RF devices, and/or optical devices (e.g., optical switches). A MEMS device is typically formed on a substrate (e.g., a silicon or silicon-on-insulator wafer) using various micromachining techniques such as etching into the substrate and/or depositing/patterning various materials.

In embodiments of the present invention, a nickel-based material is used on one or both wafers to be bonded, and the two wafers are bonded at low temperature and pressure through interdiffusion of the nickel-based material with either another nickel-based material or aluminum. Specifically, in various embodiments, nickel-based walls are formed on one wafer, and corresponding walls are formed on the other wafer from a nickel-based material or aluminum. The walls of the two wafers are placed in contact with one another under sufficient bonding force and temperature to cause bonding of the walls through interdiffusion. Generally speaking, the force applied to the wafers effectively only needs to be sufficient (i.e., above a predetermined threshold) to maintain contact of the bonding surfaces during the bonding process, and above the threshold, the force is generally independent of the surface area to be bonded such that increases in wafer size and/or device density do not require substantial increases in bonding force (or perhaps any increase at all).

In certain embodiments of the present invention, one of the wafers may be a MEMS device wafer having a number of MEMS devices. The other wafer may be, for example, a cap wafer or another MEMS device wafer. One, the other, or both wafers may include electronic circuitry. Walls may be configured on the two wafers so as to produce sealed MEMS devices (i.e., wherein the MEMS device is completely enclosed and sealed within a capped cavity, which may be filled with a fluid such as a gas or liquid or may be fully or partially evacuated). Alternatively, the walls may be configured so as to leave openings that permit a component of the MEMS device to be exposed to the outside environment (e.g., a diaphragm of a MEMS microphone or pressure sensor).

In certain embodiments, nickel walls are used on one wafer (e.g., the cap wafer for capped MEMS devices) and aluminum walls are used on the other wafer (e.g., the MEMS device wafer). Both nickel and aluminum are compatible with typical CMOS/MEMS fabrication processes, and the nickel walls may be formed, for example, from either a sputtered nickel thin film or an electroless or electroplated nickel layer that is wet etch patterned to form the desired configuration of walls. The two wafers are brought into contact at a sufficient temperature and bonding force (e.g., around 450-470 degrees Celsius and a bond force of around 9-18 KN in one exemplary embodiment) to cause bonding of the nickel and aluminum through interdiffusion, specifically forming a stable Al/Al(1+x)Ni/AlNi(1+y)/Ni composite layer consisting of soft pure metal base and hard intermediate phase alloy dispersed to strengthen the matrix. This nickel-aluminum bonding generally forms a metal alloy hermetic seal, and the nickel-aluminum bond is electrically conductive and therefore may be used in specific embodiments for an electrically conductive path between the device and cap wafers (e.g., to provide electrical connectivity to the device on the device wafer through nickel-filled through-wafer vias in the cap wafer, which may be formed, for example, using electroless or electroplated nickel at the back end of fabrication and integrated with this Ni—Al wafer bonding for wafer-level chip-scale packaging (WLCSP) applications). Unlike thermocompression bonding (e.g., Al—Al bonding, or more specifically Al₂O₃—Al₂O₃ due to the ready oxidation of aluminum), in which the process bonding force is dependent upon the surface area to be bonded (and hence is sensitive to such things as wall thickness, number of die per wafer, and wafer size) and generally requires bonding at specific eutectic temperature, this nickel-aluminum bonding is generally independent of surface area to be bonded, and the process temperature window is generally wider because it does not involve eutectic bonding and therefore generally does not require a specific eutectic temperature.

In various alternative embodiments, nickel walls may be used on one wafer (e.g., the cap wafer) with Ni—Al alloy walls used on the other wafer (e.g., the MEMS device wafer); nickel walls may be used on both wafers; Ni—Al alloy walls may be used on both wafers; or Ni—Al alloy walls may be used on one wafer (e.g., the cap wafer) with aluminum walls used on the other wafer (e.g., the MEMS device wafer).

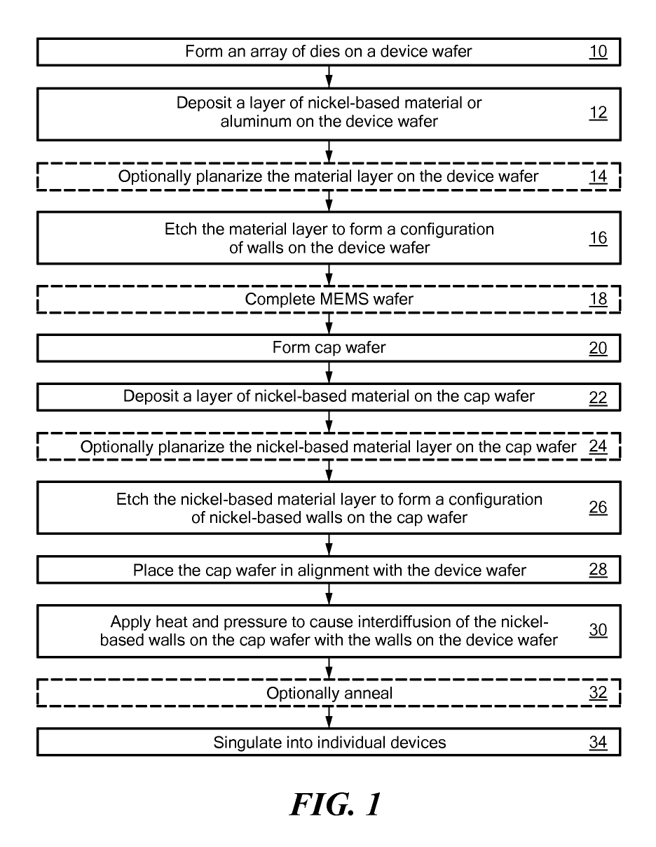

FIG. 1 schematically shows an illustrative process of making capped MEMS devices in accordance with an exemplary embodiment of the present invention. It should be noted that various steps of this process may be performed in a different order than that discussed. In addition, those skilled in the art should understand that additional steps may be performed, while others may be omitted.

An arrangement of MEMS devices is formed 10 on a first wafer. The wafer is preferably a semiconductor material and more particularly, a silicon-based material having MEMS devices formed thereon. Silicon-based materials include single crystal silicon, silicon germanium, and silicon-on-insulator (SOI). In alternative embodiments, however, other types of materials may be used. While conventional processes may be used to form the arrangement of MEMS devices on the wafer, in accordance with embodiments of the present invention, it will be possible to more closely space the dies relative to one another than was practical with glass frit bonding. As a result, a greater number of devices can be made from a single wafer. The device wafer may include electronic circuitry.

An arrangement of walls is formed on a top surface of the first wafer from a nickel-based material or aluminum. For example, a layer of material may be deposited 12 and then etched 16 to leave a desired arrangement of walls. The walls may be formed in ring configurations surrounding each MEMS devices or may be formed in other configurations, e.g., non-contiguously so as to leave openings in the capped wafer device such as for allowing sound waves to reach a microphone diaphragm or pressure to reach a pressure sensor. It is often desirable to apply a diffusion barrier (e.g., titanium-tungsten) to the wafer before depositing the material. The diffusion barrier helps adhere the material and also serves to prevent spiking. In other words, it acts as a barrier against diffusion of the material and silicon into each other. The material layer may be more than one or two microns in thickness. Given a substantially flat substrate and the general conformability of nickel-based and aluminum films when they yield, a thickness near two microns is generally sufficient to achieve bonding. But if necessary, planarization 14 may be conducted to achieve the desirable flat surface.

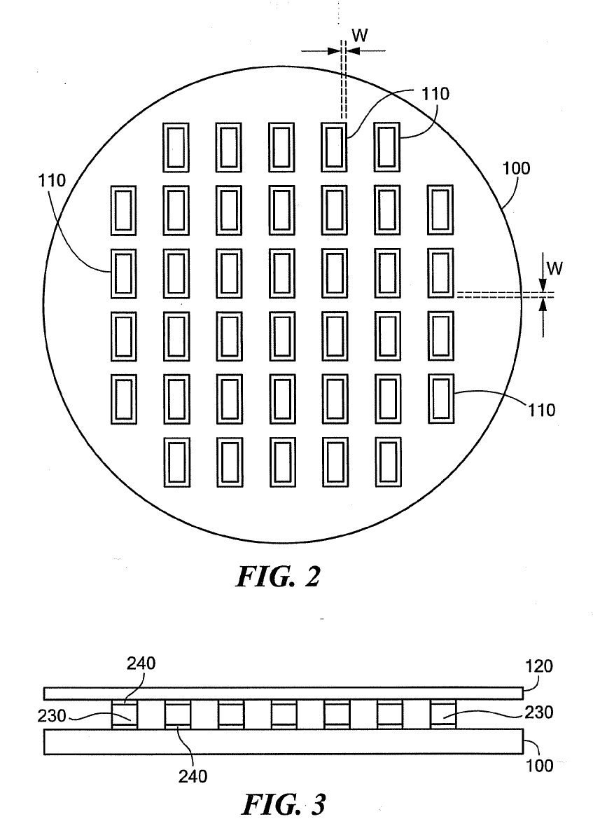

A exemplary wafer 100 with an array of walls 110 thereon after etching (i.e., in the form of rings in this example) is illustrated in FIG. 2. The array of walls 110 coincides with the array of MEMS devices, such that each MEMS device is surrounded by a wall. For convenience, the walls 110 are shown spaced apart from one another, but in typical embodiments, the walls 110 would be very close together, and in some embodiments, a single wall portion may be placed between adjacent MEMS devices so as to tightly pack MEMS devices on the device wafer. The wall width W of each wall is advantageously small, thereby providing smaller size dies and allowing a greater density of MEMS devices to be made on a single wafer. The wall width may be between 3 and 90 microns, or more preferably between 5 and 30 microns.

In the specific case of making MEMS devices, conventional micromachining may be used to form MEMS dies and complete 18 the MEMS wafer. For example, the microelectromechanical structures may be formed through various deposition and etching processes. For each device, a microelectromechanical structure is typically released so as to be movable with respect to the die to which it is attached. The wall coincident with the die surrounds the area occupied by microelectromechanical structure. MEMS wafers may or may not include electronic circuitry.

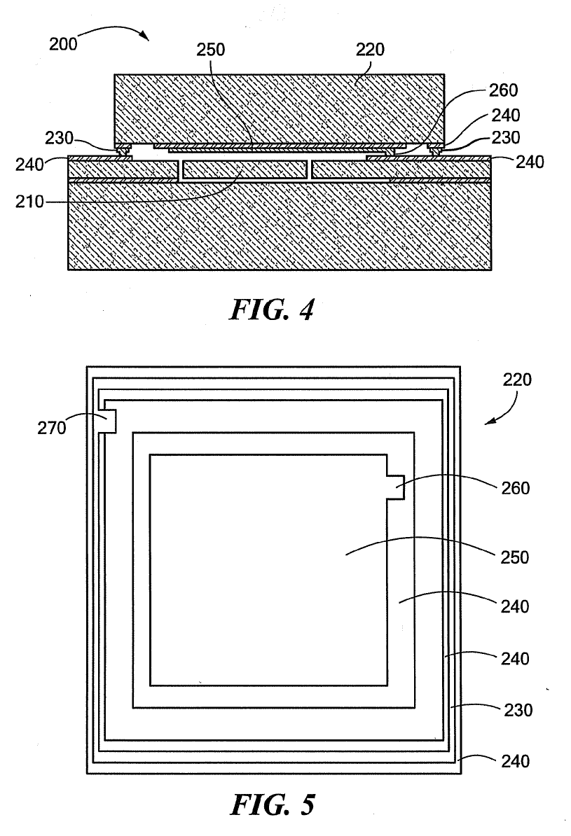

A cap wafer 120 is also formed 20. In a manner similar to the first wafer, the cap wafer may be formed from single crystal silicon or other material in accordance with conventional processes (e.g., surface and bulk micromachining processes). The cap wafer and hence the caps may be flat as shown in FIG. 4. Alternatively, the cap wafer may be formed with an array of cavities, one for each cap to accommodate movement of microstructures on the die to which it gets bonded. Additionally or alternatively, the cap wafer may include microelectronic devices (e.g., MEMS devices) and/or may include electronic circuitry.

Similar to the first wafer, an arrangement of nickel-based walls is formed on a bottom surface of the second wafer, e.g., by depositing 12 a layer of nickel-based material on the bottom side of the cap wafer and then etching 26 to leave a desired arrangement of nickel-based walls, typically one for each of the MEMS devices. The deposition may be performed, for example, by sputtering. In embodiments in which nickel-based material is used on both wafers, the nickel-based materials used on the two wafers may be the same or different. For example, one wafer can use nickel while the other uses a nickel-aluminum alloy. As was the case for the first wafer, a diffusion barrier may be applied before depositing the nickel-based material The nickel-based layer may be more than one or two microns thick. Again, the layer may be sufficiently flat as deposited or it may be put through a planarizing 24 process to achieve desired flatness.

In alternative embodiments, a nickel-based area may be left within each ring in the cap, e.g., for use as a z-axis electrode. As indicated above, the wall width of each wall is advantageously small, thereby allowing a greater density of devices to be made with a single wafer. The wall width may be between 3 and 90 microns, or more preferably between 5 and 30 microns. It may be useful to make the wall widths on one wafer (typically the cap wafer) slightly wider than the wall width on the other wafer. By including walls with a wider wall than its corresponding walls on the opposing wafer, slight misalignments of the two wafers can be tolerated. The metallized cap wafer then may be placed 28 with respect to the first wafer so that the array of walls on the first wafer contacts and aligns with the array of nickel-based walls on the second wafer. Differing wall widths offers a less exacting requirement when aligning the arrays. The narrow wall does not need to be centered on the wider wall. It should, however, be in contact with the wider wall over the entire width of the narrow wall. Alignment is generally achieved before placing the wafer pair into a wafer bonder on one of the bonder platens. The platens in the wafer bonder may be inside a chamber to allow control of vacuum level, gas composition, and/or gas pressure. With this capability, gases may be evacuated and backfilled one or more times in order to create the desired bond environment. Clean surfaces will bond at lower pressures and temperatures. If a gap is held between the aligned wafers, as is typically the case, a reactive gas may optionally be introduced into the bond chamber during this process in order to clean the bond surfaces at a temperature not to exceed 500° C. The gas can react with any contamination on the wall surfaces, especially on aluminum walls. Examples of such reactive gases include forming gas and formic acid. The gap between the aligned wafers might be held at between 10 to 500 microns by suitably sized spacers. After the optional cleaning step, the bond chamber environment is adjusted to the desired vacuum level or gas composition and pressure. While if forming gas is used it may remain in the chamber, in the case of formic acid, it is recommended that the chamber be evacuated and backfilled after cleaning.

The heated platens of the bonder place the walls of the device and cap wafers into contact with one another at a temperature and bonding force sufficient to form a wafer bond through interdiffusion of the walls. In exemplary embodiments, the temperature may be less than around 500° C. and more specifically may be around 450° C. to 470° C., and the bonding force may be between around 9 and 18 KN. The actual temperature and bonding force used in a particular embodiment may depend on various factors, including, among other things, the materials selected and whether or not an anti-stiction film (used in some MEMS devices) is present. An example of such an anti-stiction treatment is contained in U.S. Pat. No. 7,220,614, “Process for Wafer Level Treatment to Reduce Stiction and Passivate Micromachined Surfaces and Compounds Used Therefor”, the full disclosure of which is hereby incorporated by reference herein. After bonding is complete, bond strength may be improved, for example, by annealing the bonded wafer pair, at a temperature of about 450° C. for example.

For the wafers to be adequately bonded through interdiffusion, the walls must have been subjected to an adequate minimum bonding force. To obtain high yield of bonded devices, it should be ensured that the minimum bonding force be applied over the entire area of the wafers occupied by the devices. Even high quality wafers generally have small local thickness variations. In addition, it has been found that platens on some wafer bonders may deform slightly when bonding forces are applied at elevated temperatures. These small effects may cause the bonder to apply insufficient bonding force to achieve robust bonds in local areas. One response is to increase the overall force. However, this may be limited by bonder capacity. Another approach is to insert graphite films above and/or below the pair of wafers being bonded. Under pressure, the graphite deforms to substantially equalize the bonding force across the wafers. Soft graphite may also reduce wafer cracking initiated by particle contaminants on either the bonder or wafer surfaces.

After the wafers are held at the target temperature and bonding force for a suitable time, the bonded wafer pair is cooled and the bonding force is released. The resulting intermediate product is bonded wafers. FIG. 3 is a schematic diagram showing a side view of two bonded wafers with bonded walls forming seal rings 230 between a die and its cap. If sufficient bonding force was applied in the process, the seal ring should form a hermetic seal between the die and the cap. The seal rings typically also create a gap between the die and the cap, which may be filled with a fluid or partially or fully evacuated (e.g., to form a vacuum). The seal rings typically are also electrically conductive and therefore may be used for electrical connectivity between the die and the cap, e.g., to drive the cap potential or to form a ground shield for the device in specific applications. Alternatively, the conductive seal ring may be electrically isolated from the die and the cap by dielectric layers 240.

Further processing of the bonded wafers may be performed according to conventional techniques. For example, the bottom portion of the first wafer may be subjected to a thinning process (e.g., backgrinding or etch back processes) to expose vias in the dies. Conductive contacts can then be mounted to the bottom of the vias, which then can be mounted to corresponding contacts on the top surface of a circuit die. After any such post-bonding processing is completed, the wafers then can be singulated into individual devices. Singulation is a cutting or dicing operation (e.g., using a saw or laser) that separates the individual devices. There may be a sequence of singulation steps in order to singulate caps before completing singulation of the individual devices through the wafer carrying the dies. The resulting devices may be mounted in a package, flip chip mounted on a circuit board (after contacts are formed on one side), or used in any conventional manner.

Another embodiment of the invention more generally relates to forming electrical contacts between a first wafer and a second wafer. It includes depositing a nickel-based material on one semiconductor wafer and depositing a nickel-based material or aluminum on a second semiconductor wafer. The resulting layers are preferably etched to form an array of contacts. The wafers are placed together with their respective contacts in alignment. This is preferably performed before placing the wafer pair into a wafer bonder on one of the bonder platens. The platens in the wafer bonder may be inside a chamber to allow control of vacuum level, gas composition, and/or gas pressure. With this capability, gases may be evacuated and backfilled one or more times in order to create the desired bond environment. If a gap is held between the aligned wafers, a reactive gas may optionally be introduced into the bond chamber during this process in order to clean the bond surfaces at a temperature not to exceed 500° C. Examples of such reactive gases include forming gas and formic acid. After the optional cleaning step, the bond chamber environment is adjusted to the desired vacuum level or gas composition and pressure. The wafers are then brought into contact (if not already in contact) and compressed between the heated platens in order to bond the contacts on the first wafer to their respective contacts on the second wafer. After the wafers are held at the target temperature and bonding force for a suitable time, the bonded wafer pair is cooled and the force removed. The bonded pair may optionally be annealed at this point. In a preferred embodiment, the heating need does not exceed 500° C. In exemplary embodiments, the temperature may be less than around 500° C. and more specifically may be around 450° C. to 470° C., and the bonding force may be between around 9 and 18 KN. Bond strength may be improved by annealing the bonded wafer pair, at a temperature of about 450° C. for example. In addition, it may be helpful to planarize the contacts before bonding. After the bond process is completed, the bonded wafers are singulated to form individual semiconductor devices, each with bonded electrical connections between layers. There may be a sequence of singulation steps in order to individually singulate portions of the first wafer and portions the second wafer. The die formed in this process have at least two layers of silicon mechanically joined at least in part by nickel-based structures. One or more of the nickel-based structures may function as electrically active connections electrically isolated from each other. The die may or may not incorporate a MEMS device. While bonding of wafers and forming of interconnects has been described with respect to two wafers, the methods set forth herein also apply to bonding and interconnects between more than two wafers.

Without limiting the application of embodiments of the invention to any particular semiconductor device or MEMS device, it is worthwhile to note a few examples, such as inertial sensors. Inertial sensors are used for single and multi-axis accelerometers and gyroscopes. In certain accelerometers, for example, the microelectromechanical structure is a movable mass that is movably mounted to the semiconductor die with anchors so that it can move back and forth along a desired axis. The mass has fingers extending perpendicular to the axis and between sets of stationary parallel plates. When the fingers move, a change in capacitance between the plates is detected, thus allowing the acceleration of the mass along the axis to be determined.

Reference is now made to FIGS. 4 and 5, which illustrate one specific type of device manufacturable by the above-described method. This exemplary MEMS device conventionally includes a semiconductor die 200, a microelectromechanical structure 210 movably attached to the semiconductor die, and a cap 220. Manufacture of the microelectromechanical structure on the semiconductor die can be effected by any of a variety of accepted processes. In accordance with embodiments of the present invention, the cap 220 is bonded to the semiconductor die by an electrically conductive seal 230 that includes nickel and/or nickel alloy. The illustration exaggerates the difference in wall widths of the walls that make up the conductive seal 230 for ease of understanding. It should be understood that after bonding, this has become a single seal 230 with atomic contact between the original separate walls. The nickel, aluminum, and nickel-aluminum alloy materials generally exhibit the characteristic of not spreading much when bonded. Thus, the wall widths can be small and repeatable in manufacture. The wall width may be between 3 and 90 microns wide, or more preferably between 5 and 30 microns wide. The seal 230 forms a hermetic seal between the die 200 and the cap 220. A dielectric layer 240 may be included on one or both of the wafers to electrically isolate the conductive seal 230 from the underlying substrate.

In alternative embodiments, a nickel-based electrode 250 may be left on the cap wafer 220. Such an electrode can be used as part of a z-axis sensor. The electrode 250 can be electrically connected to the semiconductor die through a bond pad 260, bonded to the electrode during bonding. The bond pad 260 is an example of an electrical interconnect formed by use of bonding. It was formed from aligned nickel-based deposits on the cap wafer and the die wafer. Accuracy of the z-axis sensor can be enhanced by use of a fixed reference electrode 270 formed on the semiconductor die adjacent to the movable structure 210, as shown in FIG. 5.

The conductivity afforded by the nickel-based seal ring 230 can be harnessed by providing an electrical connection pad 270. In FIG. 5, the pad 270 is shown in electrical contact with the cap 220. Such an electrical connection can be used for connecting to the cap in order to control its electrical potential for a variety of reasons such as formation of an electrical shield.

The embodiments of the invention described above are intended to be merely exemplary; numerous variations and modifications will be apparent to those skilled in the art. All such variations and modifications are intended to be within the scope of the present invention as defined in any appended claims.

What is claimed is:

1. Bonded wafers comprising:
a first wafer including an array of semiconductor dies, each semiconductor die including a microelectronic device;
a second wafer; and
a configuration of walls forming a bond between the first wafer and the second wafer, wherein each wall comprises an interdiffusion of a first nickel-based material on one wafer with one of a second nickel-based material and aluminum on the other wafer.

2. The bonded wafers of claim 1, wherein the wall comprises an interdiffusion of nickel on one wafer with aluminum on the other wafer.

3. The bonded wafers of claim 2, wherein the wall comprises an interdiffusion of aluminum on the first wafer and nickel on the second wafer.

4. The bonded wafers of claim 1, wherein the wall comprises an interdiffusion of the same or different nickel-based materials on both wafers.

5. The bonded wafers of claim 1, wherein the walls are configured to hermetically seal each of the microelectronic devices in a respective cavity.

6. The bonded wafers of claim 1, wherein at least one of:
the walls hold the first wafer and second wafer at least 2 microns apart;
the walls have a wall width of between 3 and 90 microns;
the second wafer includes an array of semiconductor dies, each semiconductor die including a microelectronic device;
at least one of the wafers includes electronic circuitry; and
the microelectronic devices are MEMS devices.

7. A MEMS device comprising:
a device die including a microelectronic device;
a cap die; and
a wall bonded between the device die and the cap die and at least partially surrounding an area occupied by the microelectronic device, the wall comprising an interdiffusion of a first nickel-based material on one die with one of a second nickel-based material and aluminum on the other die.

8. The MEMS device of claim 7, wherein the wall comprises an interdiffusion of nickel on one die with aluminum on the other die.

9. The MEMS device of claim 8, wherein the wall comprises an interdiffusion of aluminum on the device die and nickel on the cap die.

10. The MEMS device of claim 7, wherein the wall comprises an interdiffusion of the same or different nickel-based materials on both dies.

11. The MEMS device of claim 7, wherein the wall is configured to hermetically seal the microelectronic device in a cavity.

12. The MEMS device of claim 7, wherein at least one of:
the wall holds the device die and the cap die at least 2 microns apart;
the walls have a wall width of between 3 and 90 microns;
the cap die includes a microelectronic device;
at least one of the dies includes electronic circuitry; and
the microelectronic device is a MEMS device.

13. A method of making semiconductor devices comprising:
depositing a nickel-based material to form a nickel-based layer on a first semiconductor wafer;
patterning the nickel-based layer to form a first configuration of nickel-based walls on the first semiconductor wafer;
depositing one of a nickel-based material and aluminum to form a material layer on a second semiconductor wafer;
patterning the material layer to form a configuration of material walls on the second semiconductor wafer;
placing the second wafer on the first wafer so that the configuration of nickel-based walls on the first wafer aligns with the configuration of walls on the second wafer;
heating the first and second wafers;
compressing the first and second wafers against each other to form a bond between the walls on the first wafer and their respective walls on the second wafer through interdiffusion; and
singulating the first and second wafers into individual semiconductor devices, each having bonded wall.

14. The method of claim 13, wherein patterning comprises etching.

15. The method of claim 13, wherein heating is performed at a temperature less than 500° C.

16. The method of claim 15, wherein compressing applies a force between around 9 and 18 KN.

17. The method of claim 13, wherein the nickel-based walls are nickel walls and wherein the material walls are aluminum walls.

18. The method of claim 13, wherein the nickel-based walls and the material walls include the same or different nickel-based materials.

19. The method of claim 13, wherein at least one of the wafers includes an array of semiconductor dies, each semiconductor die including a microelectronic device, and wherein the walls are configured to hermetically seal each of the microelectronic devices in a respective cavity.

20. The method of claim 13, wherein at least one of:
the walls hold the first wafer and second wafer at least 2 microns apart;
the walls have a wall width of between 3 and 90 microns; and
at least one of the wafers includes electronic circuitry.
